(19) United States
(12) Patent Application Publication
(10) Pub. No.: US 2006/0252265 A1
(43) Pub. Date: Nov. 9, 2006

(54) Etching high-kappa dielectric materials with good high-kappa foot control and silicon recess control

(76) Inventors: Guangxiang Jin, San Jose, CA (US); Meihua Shen, Fremont, CA (US)

Correspondence Address: PATTERSON & SHERIDAN, LLP;APPLIED MATERIALS INC, 595 SHREWSBURY AVE, SUITE 100, SHREWSBURY, NJ, 07702, US

(21) Appl. No.: 11/126,472

(22) Filed: May 11, 2005

Related U.S. Application Data
(63) Continuation-in-part of application No. 10/805,890, filed on Mar. 22, 2004.
Application No. 10/805,890 is a continuation of application No. 10/092,795, filed on Mar. 6, 2002, now Pat. No. 6,806,095.
(63) Continuation-in-part of application No. 10/301,239, filed on Nov. 20, 2002.

(51) Int. Cl. C23F 1/00; H01L 21/302

(52) U.S. Cl. 438/689; 216/67

(57) ABSTRACT

An apparatus and a method for etching high dielectric constant (high-κ) materials using halogen containing gas and reducing gas chemistries are provided. One embodiment of the method is accomplished by etching a layer using two etch gas chemistries in separate steps. The first etch gas chemistry contain no oxygen containing gas in order to break through etching of the high dielectric constant materials, to dean any residues left from previous polysilicon etch process resulting in less high-κ foot, and also to control silicon recess problem associated with an underlying silicon oxide layer. The second over-etch gas chemistry provides a high etch selectivity for high dielectric constant materials over silicon oxide materials to be combined with low source power to further reduce silicon substrate oxidation problem.

### CROSS-REFERENCE TO RELATED APPLICATIONS

This application is a continuation-in-part of co-pending U.S. patent application Ser. No. 10/805,890, filed Mar. 22, 2004 (Attorney Docket No. APPM/7017.C1), which is a continuation of U.S. patent application Ser. No. 10/092,795, filed Mar. 6, 2002 (Attorney Docket No. APPM/7017). This application is also a continuation-in-part of co-pending U.S. patent application Ser. No. 10/301,239, filed Nov. 20, 2002 (Attorney Docket No. APPM17982). Each of the aforementioned related patent applications is herein incorporated by reference.

### BACKGROUND OF THE INVENTION

1. Field of the Invention

Embodiments of the present invention generally relate to a method of dry etching semiconductor substrates. More specifically, the invention relates to a method of etching high-κ dielectric materials using a gas mixture comprising a halogen gas and a reducing gas.

2. Description of the Related Art

Field effect transistors that are used in forming integrated circuit generally utilize a polysilicon gate electrodes deposited upon a gate dielectric that separates the electrode from the channel between source and drain regions. In prior art transistor structures, the gate dielectric is typically fabricated of silicon dioxide (SiO₂). However, as integrated circuit transistors have become smaller (on the order of 100 nanometers in width), the thickness of the dielectric material in the gate structure has become thinner than 10 Angstroms. With such a thin dielectric, electrons can propagate from the polysilicon gate electrode into the transistor channel causing the transistor to operate improperly or become defective.

This leakage of electrons from the gate electrode through the gate oxide has led researchers to investigate the use of more stable high-κ dielectric materials as gate dielectric materials. One very stable dielectric material having a high dielectric constant is hafnium oxide (HfO₂). However, most high-κ materials are so stable that it is very difficult to etch even a thin layer of high-κ material using conventional silicon oxide etchants in order to form gate structures without damaging or etching other material layers above or below the layer containing a high-κ material. Thus, the etch selectivity for the high-κ material to other materials on the gate structures, such as silicon oxide, polysilicon and silicon, has to be very high in order to protect or passivate the side wall of the above polysilicon layer or the surface of the underlying silicon oxide layer.

In addition, when the layer containing a high-κ material is on top of a silicon oxide layer, oxygen in conventional etching processes may also penetrate the underlying silicon oxide layer on the substrate surface and oxidize the silicon substrate, resulting in a void space, also known as silicon recess, in the underlying silicon oxide layer after the next post-etch hydrofluoric acid dip wet dean treatment. Further, an unmasked portion of the layer containing the high-κ material may not be etched uniformly and often results in residual high-κ materials left extending from the masked portion of the layer containing the high-κ material into the unmasked area of a substrate surface, also know as high-κ foot The high-κ foot effect may be severe when there is residual polysilicon gate electrode material left on the substrate surface.

Therefore, there is a need in the art for a high-κ material etching process with very high selectivity to other materials and good control over silicon recess and high-κ foot problems.

### SUMMARY OF THE INVENTION

The invention generally provides an apparatus and a method for etching high dielectric constant materials using halogen containing gas and reducing gas chemistries. In one embodiment, a method of plasma etching a substrate having a layer containing a high-κ material includes exposing the layer to a plasma formed from a first process gas mixture having a first halogen containing gas without introducing an oxygen containing gas inside an etch chamber, and etching at least a portion of the layer without oxidizing a portion of the substrate. The method further includes etching the layer using a plasma formed from a second process gas mixture having a second halogen containing gas and carbon monoxide.

In another embodiment, a method of plasma etching a substrate having a layer containing a high-κ material includes etching at least a portion of the layer with a plasma formed from a first process gas having a first halogen containing gas at a substrate bias power of 100 Wafts (W) or less, and etching the layer to a plasma formed from a second process gas mixture comprising a second halogen containing gas and carbon monoxide with a high selectivity to the layer and at a source power of between about 200 W to about 800 W.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic diagram of a plasma processing apparatus used in performing the etching processes according to one embodiment of the invention.

FIG. 2 depicts a process flow diagram illustrating a first method incorporating one embodiment of the invention.

FIG. 3 depicts a process flow diagram illustrating a second method incorporating one embodiment of the invention.

FIG. 4 depicts a process flow diagram illustrating a third method incorporating one embodiment of the invention.

FIG. 5A depicts a schematic cross-sectional view of a substrate having a layer containing a high-κ material used in performing the etching processes according to one embodiment of the invention.

FIG. 5B depicts a schematic cross-sectional view of a gate structure having a conventionally etched high dielectric constant material layer that has high-κ foot control and silicon recess problems.

FIG. 5C depicts a schematic cross-sectional view of a gate structure having the high dielectric constant material layer of FIG. 5A that has been etched with good control of a high-κ foot and silicon recess according to embodiments of the invention.

FIG. 6A illustrates the presence of a high-κ foot using a prior art method.

FIG. 6B illustrates reduction of a high-κ foot according to one embodiment of the invention.

FIG. 7A illustrates the presence of silicon recess using a prior art method.

FIG. 7B illustrates the absence of silicon recess according to one embodiment of the invention.

FIG. 8A illustrates the presence of a high-κ foot and silicon recess problems using a prior art method.

FIG. 8B illustrates eliminating a high-κ foot and silicon recess problems according to embodiments of the invention.

### DETAILED DESCRIPTION

The invention generally relates to methods and apparatus for etching a substrate having high-κ materials deposited thereon. The method includes plasma etching one or more portions of a layer containing a high-κ material in one or more steps using one or more etching gas chemistries (gas mixtures). The method can be practiced as either a single-step etch process or a two-step etch process. The two-step etch process include break through etch and overetch step, where the first break through etch step uses an oxygen-free etching chemistry to prevent diffusion of oxygen (O₂) through the layer containing the high-κ material into underlying silicon (Si) substrate. Such diffusion of oxygen undesirably creates silicon dioxide (SiO₂) in the channel, source, and drain regions of a transistor. The overetch step includes an etch chemistry with high selectivity for etching the high-κ material as compared to other materials, such as polysilicon and silicon oxide. The etch process of the invention can be reduced to practice in any plasma etch chamber, for example, a Decoupled Plasma Source (DPS) etch process chamber in a CENTURA® etch system or a DPS-II etch chamber, both of which are available from Applied Materials, Inc. of Santa Clara, Calif.

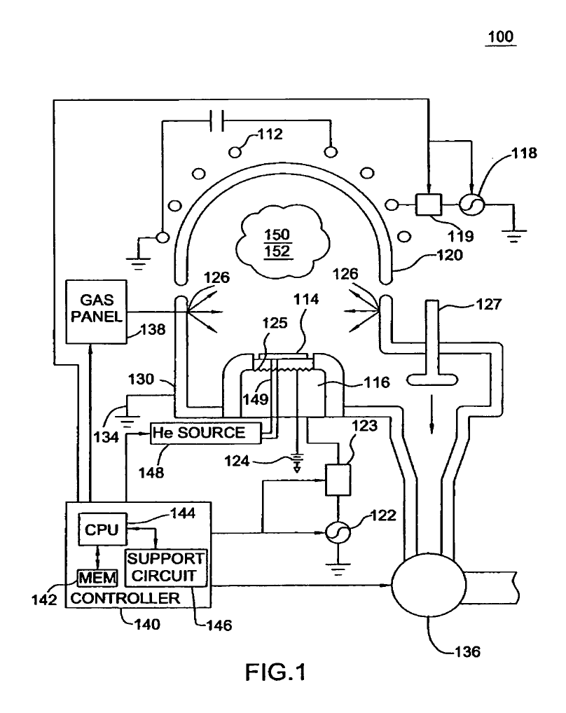

FIG. 1 depicts a schematic diagram of the DPS etch process chamber 100, that comprises at least one inductive coil antenna segment 112, positioned exterior to a dielectric, dome-shaped ceiling 120 (referred to herein as the dome 120). Other chambers may have other types of ceilings, e.g., a flat ceiling. The antenna segment 112 is coupled to a radio-frequency (RF) source 118 through a matching network 119. In one embodiment, the source RF power applied to the inductive coil antenna 112 is in a range between about 200 Watts to about 2500 Watts at a frequency between about 50 kHz and 13.56 MHz. In another embodiment, the source RF power applied to the inductive coil antenna 112 is in a range between about 200 Wafts to about 800 Watts, such as at about 400 Watts.

The process chamber 100 also includes a substrate support pedestal 116 (biasing element) that is coupled to a second (biasing) RF source 122 that is generally capable of producing an RF signal to generate a bias power of about 500 Wafts or less (e.g., no bias power) at a frequency of approximately 13.56 MHz. The biasing source 122 is coupled to the substrate support pedestal 116 through a matching network 123. The bias power applied to the substrate support pedestal 116 may be DC or RF. The chamber 100 also contains a conductive chamber wall 130 that is connected to an electrical ground 134. A controller 140 including a central processing unit (CPU) 144, a memory 142, and support circuits 146 for the CPU 144 is coupled to the various components of the DPS etch process chamber 100 to facilitate control of the etch process.

In operation, a substrate 114 is placed on the substrate support pedestal 116 and is retained thereon by conventional techniques, such as electrostatic chucking or mechanical clamping of the substrate 114. Gaseous components are supplied from a gas panel 138 to the process chamber 100 through entry ports 126 to form a gaseous mixture 150. The gaseous mixture 150 is ignited into a plasma 152 in the process chamber 100 by applying RF power from the RF sources 118 and 122, respectively, to the antenna 112 and the substrate support pedestal 116. The pressure within the interior of the etch chamber 100 is controlled using a throttle valve 127 situated between the chamber 100 and a vacuum pump 136. The temperature at the surface of the chamber walls 130 is controlled using liquid-containing conduits (not shown) that are located in the walls 130 of the chamber 110.

The temperature of the substrate 114 is controlled by stabilizing the temperature of the support pedestal 116 and flowing helium gas from source 148 via conduit 149 to channels formed by the back of the substrate 114 and grooves (not shown) on the pedestal surface. The helium gas is used to facilitate heat transfer between the substrate support pedestal 116 and the substrate 114. During the etch process, the substrate 114 is heated by a resistive heater 125 within the substrate support pedestal 116 to a steady state temperature via a DC power source 124, and the helium facilitates uniform heating of the substrate 114. Using thermal control of both the dome 120 and the substrate support pedestal 116, the substrate 114 is maintained at a temperature of between about 100 degrees Celsius and about 500 degrees Celsius.

Those skilled in the art will understand that other forms of etch chambers may be used to practice the invention. For example, chambers with remote plasma sources, microwave plasma chambers, electron cyclotron resonance (ECR) plasma chambers, and the like may be utilized as well to practice the invention.

To facilitate control of the chamber as described above, the CPU 144 may be one of any form of general purpose computer processor that can be used in an industrial setting for controlling various chambers and subprocessors. The memory 142 is coupled to the CPU 144. The memory 142, or computer-readable medium, may be one or more of readily available memory such as random access memory (RAM), read only memory (ROM), floppy disk, hard disk, or any other form of digital storage, local or remote. The support circuits 146 are coupled to the CPU 144 for supporting the processor in a conventional manner. These circuits include cache, power supplies, clock circuits, input/output circuitry and subsystems, and the like. An etching process is generally stored in the memory 142 as a software routine. The software routine may also be stored and/or executed by a second CPU (not shown) that is remotely located from the hardware being controlled by the CPU 144.

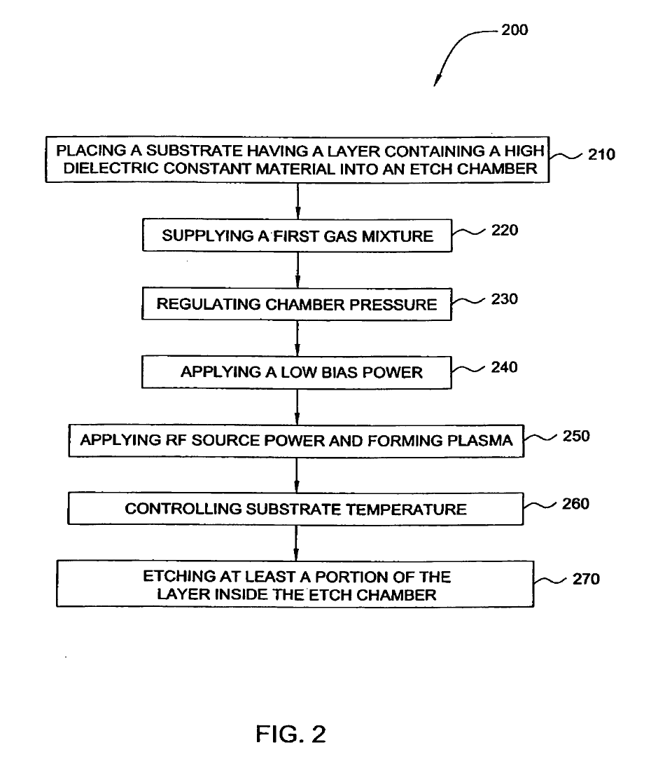

The high-κ foot and silicon recess problems associated with the prior art are overcome by the invention for etching materials with high dielectric constants materials using methods illustrated in FIGS. 2-4. High-κ materials of the invention include those having dielectric constant greater than 4.0, including hafnium dioxide (HfO₂), zirconium dioxide (ZrO₂), hafnium silicon oxide (HfSiO₂), zirconium silicon oxide (ZrSiO₂), tantalum dioxide (TaO₂), aluminum oxide, aluminum doped hafnium dioxide, bismuth strontium titanium (BST), platinum zirconium titanium (PZT), among others A layer containing a high-κ material may also include a metal material for gate electrode, including tantalum, tantalum nitride, tantalum silicon nitride, titanium nitride, among others, on top of a high-κ material for forming a gate structure.

One exemplary etch method 200 is illustrated in FIG. 2. The method 200 includes placing a substrate having a layer comprising a high dielectric constant (high-κ) material into an etch chamber at step 210. The substrate could be any semiconductor substrates, silicon wafers or glass substrates. At least a portion of the layer containing the high-κ material is exposed for etching, for example, through one or more openings in a patterned mask.

At step 220, a process gas mixture is supplied into the etch chamber The process gas mixture can include a first halogen containing gas without any oxygen containing gas. The first halogen containing gas may be a chlorine containing gas, including, but not limited to, chlorine gas (Cl₂), boron chloride (BCl₃), hydrogen chloride (HCl), among others. In addition, both chlorine gas (Cl₂) and boron chloride (BCl₃) can be included in the first gas mixture. The type of halogen gas (e.g., Cl₂, BCl₃ or both) is selected to best remove the metal (e.g., hafnium, zirconium, etc.) from the layer containing the high-κ material.

The process gas mixture at step 220 can further include a reducing agent without oxygen containing gas. A suitable reducing agent includes, but is not limited to, hydrocarbon gases, such as methane (CH₄), ethane (C₂H₆), ethylene (C₂H₄), and combinations thereof. The hydrocarbon (e.g., methane) is selected to best serve as a polymerizing gas to combine with by-products produced during the etch process. Specifically, the methane is used to suppress etching of silicon material, such that a high etch selectivity for high-κ dielectric materials (e.g., HfO₂ or HfSiO₂) to silicon materials is obtained. Also, the process gas mixture can further include one or more additional gases, such as helium (He), argon (Ar), nitrogen (N₂), among others.

The invention contemplates no oxygen containing gas in the process gas mixture such that a portion of the substrate underlying the layer containing the high-κ material will not be attacked by oxygen to form silicon oxide and etched. For example, when a silicon oxide layer is underlying the layer containing the high-κ material, a silicon recess problem can be reduced. In addition, the use of the first halogen containing gas and the reducing agent in the process gas mixture as the first etching chemistry enables an isotropic break-through etching of the layer containing the high-κ material in order to clean residues after the previous etch process (e.g., polysilicon etch) and control the formation of high-κ material residue (high-κ foot) during etching of the layer. As one example, a process gas mixture of chlorine, methane, and argon are introduced into the etch chamber. As another example, a process gas mixture of chlorine, boron chloride, and argon are used as the etching chemistry. In yet another example, the process gas mixture is supplied to the etch chamber at a rate in the range of about 5 sccm to about 300 sccm of the chlorine gas (Cl₂) and about 2 sccm to about 200 sccm of the methane gas (CH₄). Such flow rates define a flow rate ratio of Cl₂ to CH₄ in the range of (0.025:1) to (150:1); for example, a flow rate ratio of Cl₂ to CH₄ of about 20:1 is used.

At step 230, chamber pressure in the presence of the process gas mixture inside the etch chamber is regulated. Generally, a pressure in the etch chamber is regulated between about 2 mTorr to about 100 mTorr. For example, a chamber pressure may be maintained at about 10 mtorr.

A low bias power is applied at step 240. The substrate bias power is generally applied to the substrate support pedestal at a power between zero and about 300 Watts. The bias power may be in a form of DC, pulsed DC, or RF power. In one embodiment, a low bias power of about 100 Watts or less is applied. In another embodiment, a zero bias power is used.

At step 250, RF source power is applied to form a plasma from the process gas mixture to etch at least a portion of the layer containing the high-κ material. For example, a power of about 200 Wafts to about 3000 Watts can be applied to an inductively coupled antenna source to ignite a plasma inside the etch chamber.

At step 260, a substrate temperature is maintained within a temperature range of about 100 degrees Celsius to about 500 degrees Celsius. In one embodiment, a high substrate temperature of about 150 degrees Celsius to about 350 degrees Celsius is used in conjunction with the first gas mixture to isotropically etch at least a portion of the layer containing the high-κ material and reduce high-κ foot residues without oxidizing the underlying silicon substrate. Accordingly, a portion of the layer containing the high-κ material is etched inside the etch chamber at step 270.

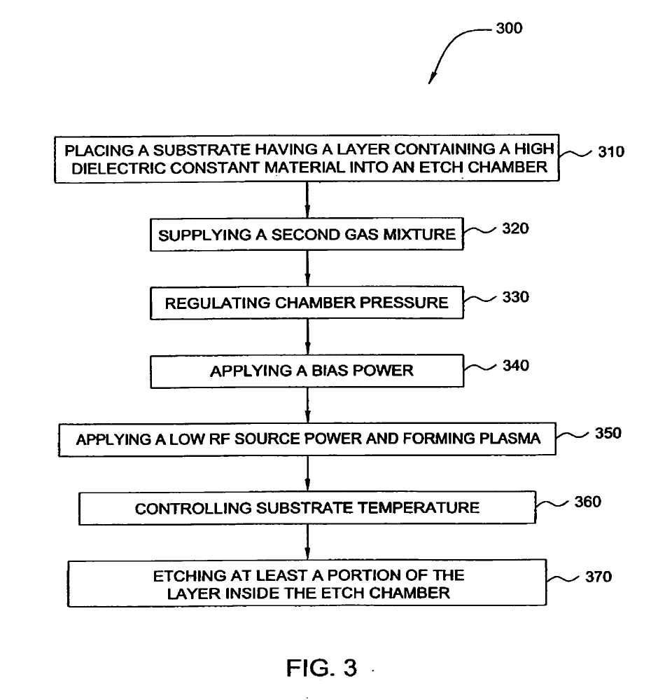

Another exemplary etch method 300 is illustrated in FIG. 3. The method 300 includes placing a substrate having a layer comprising a high dielectric constant (high-κ) material for forming a gate structure into an etch chamber at step 310. At step 320, a process gas mixture is supplied into the etch chamber. The process gas mixture can include a halogen containing gas which may be the same or different from the halogen containing gas described with reference to the method 200 above in order to etch the metal (e.g., hafnium, zirconium, etc.) from the layer containing the high-κ material. The halogen containing gas may be a chlorine containing gas, including, but not limited to, chlorine gas (Cl₂), boron chloride (BCl₃), hydrogen chloride (HCl), among others.

The process gas mixture for the method 300 can further include a reducing agent, such as carbon monoxide (CO). The reducing gas in the process gas mixture is selected to best remove the oxygen from the high dielectric constant (high-κ) material, such as the oxygen from a layer containing hafnium oxide (HfO₂). Also, the process gas mixture for the method 300 can further include an additional gas, such as helium (He), argon (Ar), nitrogen (N₂), among others. In one embodiment, chlorine, carbon monoxide, and argon are combined into the etch chamber as the process gas mixture resulting in high etch selectivity for the layer containing the high-κ material. For example, the etch selectivity of the process gas mixture for high-κ material to silicon oxide may be greater than about 30:1. As an example, the process gas mixture is supplied to the etch chamber at a rate in the range of about 20 sccm to about 300 sccm of the chlorine gas (Cl₂) and about 2 sccm to about 200 sccm of the carbon monoxide gas (CO). Such flow rates define a flow rate ratio of Cl₂ to CH₄ in the range of (1:1) to (100:1). In one embodiment, a flow rate ratio of Cl₂ to CO of about 20:1 is used. In another embodiment, a flow rate ratio of Cl₂ to CO of about 1:1 is used.

At step 330, chamber pressure of the process gas mixture inside the etch chamber is regulated to be between about 2 mTorr to about 100 mTorr. At step 340, a bias power of about 300 Watts or less is applied. In one embodiment, a low bias power of about 100 Watts or less is applied. In another embodiment, a zero bias power is used.

At step 350, a RF source power of about 200 Watts to about 2500 Watts is applied to a source to form a plasma from the process gas mixture to etch at least a portion of the layer containing the high-κ material. In one embodiment, the invention contemplates the use of a low source power of about 200 Watts to about 800 Watts, such as about 400 Watts, In conjunction with the second gas mixture to etch the layer containing the high-κ material and control the formation of a high-κ foot and silicon recess problems.

At step 360, a substrate temperature is maintained within a temperature range of about 100 degrees Celsius to about 500 degrees Celsius. In addition, a portion of the layer containing the high-κ material is etched inside the etch chamber at step 370.

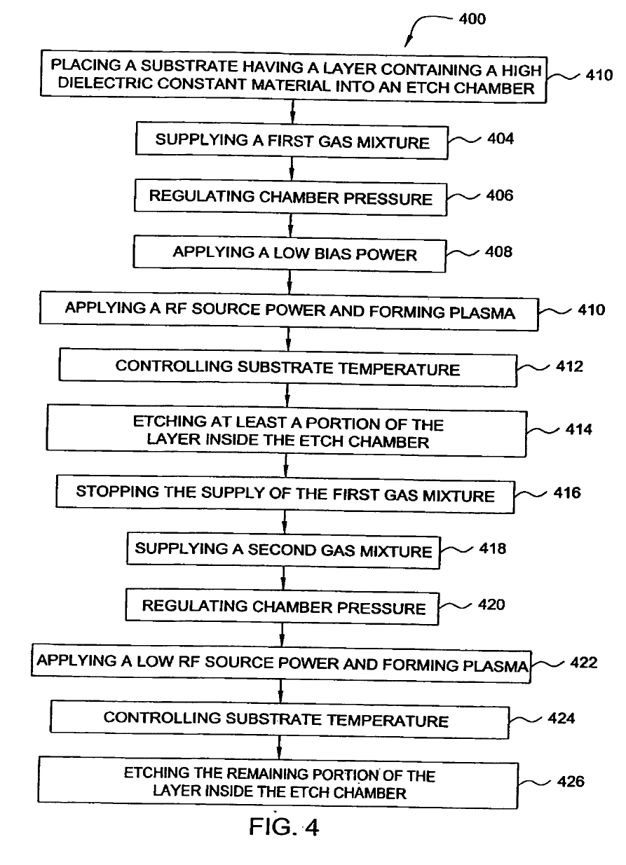

Further improvements are achieved according to one embodiment of the invention by using the oxygen-free isotropic chemistry in conjunction with a high selectivity etch chemistry in a multi-step etch process for etching a high-κ gate dielectric structure. As shown in FIG. 4, the combination of the steps of FIGS. 2 and 3 provides another embodiment of the invention.

In FIG. 4, the method 400 includes placing a substrate having a layer comprising a high dielectric constant (high-κ) material into an etch chamber at step 402 and supplying a first gas mixture as an oxygen-free isotropic etch chemistry into the etch chamber at step 404. The first gas mixture may be the same as supplied in step 220 above and may include, for example, chlorine and methane as the isotropic etching chemistry, and an optional argon gas. As another example, the first gas mixture may include chlorine and boron chloride, and optionally argon gas. In one embodiment, a low bias power of about 100 Watts or less is applied. In another embodiment, a zero bias power is used.

At step 406, chamber pressure in the presence of the first gas mixture inside the etch chamber is regulated, and at step 408, a bias power is applied. At step 410, RF source power is applied to form a plasma from the first gas mixture to etch at least a portion of the layer containing the high-κ material. At step 412, a high substrate temperature of about 150 degrees Celsius to about 350 degrees Celsius is used in conjunction with the oxygen-free first gas mixture to isotropically etch the layer containing the high-κ material and reduce high-κ foot residues without oxidizing the underlying silicon substrate. Accordingly, at least a portion of the layer containing the high-κ material is etched inside the etch chamber at step 414.

At step 416, the supply of the first gas mixture is stopped and a second gas mixture is supplied into the etch chamber at step 418. The second gas mixture may be the same as supplied in step 320 above and may include chlorine, carbon monoxide, and argon having a high etch selectivity for the layer containing the high-κ material as compared to polysilicon and silicon oxide materials. At step 420, chamber pressure of the second gas mixture inside the etch chamber is regulated, and a low source power of about 200 Watts to about 800 Watts is applied to form a plasma from the second gas mixture to etch the layer containing the high-κ material at step 422. Next, at step 424, a substrate temperature is maintained within a temperature range of about 100 degrees Celsius to about 500 degrees Celsius and at least a portion of the layer containing the high-κ material, such as the remaining unmasked portion, is etched inside the etch chamber at step 426.

The layer containing the high-κ material is etched by the methods of FIGS. 2-4 for a duration, for example, plasma etching is continued until an unmasked portion of the layer containing the high-κ material is removed. The etch time is terminated upon a certain optical emission occurring, upon a particular duration occurring, or upon some other indicator determining that the layer containing the high-κ material has been removed. It is noted that the foregoing steps of the methods 200, 300, and 400 need not be performed sequentially and embodiments of the invention do not require the steps to be performed in the order as described herein. For example, some or all of the steps may be performed simultaneously or in another order to etch a layer containing hafnium-dioxide, hafnium-silicate, or other high-κ dielectric materials. As an example, the steps of applying a low bias power and applying a RF source power may be performed simultaneously or in another order to form a plasma.

In addition, the steps can be performed as a software routine executed after a substrate 114 is positioned on the substrate support pedestal 116. The software routine, when executed by the CPU 144, transforms the general-purpose computer into a specific purpose computer (controller 140) that controls the chamber operation such that the etching methods 200, 300, and 400 can be performed. Although the process of the present invention is discussed as being implemented as a software routine, some of the method steps that are disclosed therein may be performed in hardware as well as by the software controller. As such, the invention may be implemented in software as executed upon a computer system, in hardware as an application specific integrated circuit or other type of hardware implementation, or a combination of software and hardware.

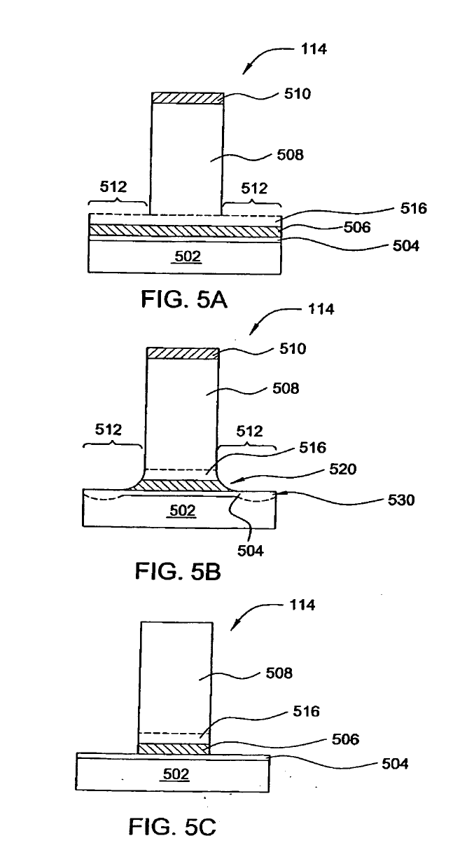

One illustrative embodiment of the inventive process is used for etching a substrate containing a film stack of FIGS. 5A and 5C to form a gate structure of a transistor. FIG. 5A depicts a schematic cross-sectional view of a substrate 114 having a layer 506 containing a high-κ dielectric material undergoing an etching process in accordance with the methods 200, 300 and 400 of FIGS. 2-4. The film stack includes a silicon substrate 502, an optional silicon dioxide layer 504, the layer 506 having a high-κ dielectric material, a polysilicon layer 508, and an etch mask 510. The layer 506 containing a high-κ dielectric material may optionally include a metal layer 516 underneath the polysilicon layer 508 for forming a gate electrode. The polysilicon layer 508 has been previously etched according to the pattern defined by the etch mask 510 to leave a portion 512 of the layer 506 containing a high-κ dielectric material exposed to the etch chemistries of the invention. The underlying silicon dioxide layer 504 will be conventionally etched after the layer 506 in region 512 is removed.

As shown in FIG. 5B, a layer 506 having a high-κ dielectric material being conventionally etched leaves behind a high-κ foot 520 and a void space 530 (silicon recess) in the silicon oxide layer 504. The result of the inventive etching method is best appreciated by referring to a gate structure depicted in FIG. 5C. As shown in FIG. 5C, a gate structure can be formed by the film stack having the polysilicon layer 508 and the layer 506 containing the high-κ material, which is etched by the method of the invention without forming the high-κ foot 520 and/or the void space 530, on top of the silicon dioxide layer 504. The silicon oxide layer 504 can be further etched as stated above. The layer 506 containing the high-κ material ensures that, during transistor operation, electrons will not flow from the gate electrode to the channel.

The following examples illustrate advantages of the present invention. A layer containing a high-κ material was etched using a DPS chamber as described in FIG. 1 that is part of an integrated processing platform, available from Applied Materials, Inc. of Santa Clara, Calif.

### EXAMPLE 1

A substrate is loaded onto the substrate support of an etch chamber and a hafnium oxide layer was etched using a gas mixture of about 40 sccm chlorine gas and about 40 sccm carbon monoxide, and argon, having a chamber pressure of about 4 mTorr and a substrate temperature of about 250 degrees Celsius. No pedestal bias power was applied to the substrate support and a RF power of about 1100 Wafts at a frequency of 13.56 MHz was applied to an antenna source to form a plasma. The hafnium-oxide layer was etched by the Cl₂/CO chemistry at an etch rate of about 100 Å/min having an etch selectivity to SiO₂ of greater than 30:1. The etch selectivity to polysilicon is greater than 3:1.

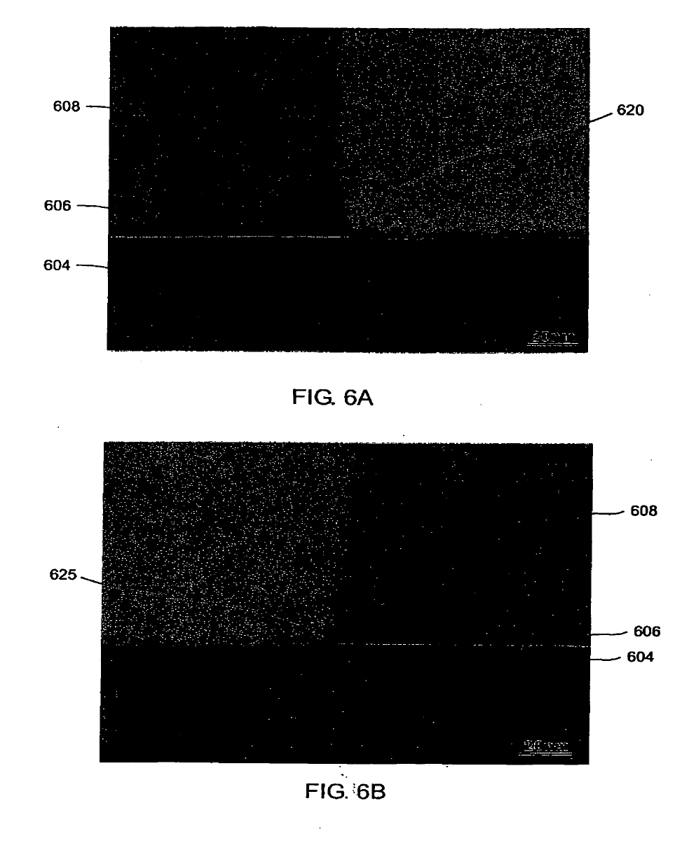

The result of the etching process is shown in FIG. 6A, illustrating a silicon dioxide substrate 604, an etched high-κ dielectric material layer 606, and a polysilicon layer 608. As shown in FIG. 6A, the etched high-κ dielectric material layer 606 includes a high-κ foot 620 which is undesirable for some semiconductor applications.

As a comparison, the results of a multi-step process are shown in FIG. 6B. The multi-step process includes an additional etch step as a first break-through step using a first etch chemistry containing chlorine (Cl₂) and methane (CH₄) before a second etch chemistry having chlorine (Cl₂) and carbon monoxide (CO). As shown in FIG. 68, the etched high-κ dielectric material layer 606 contained a reduced or no high-κ dielectric material residue 625.

### EXAMPLE 2

A substrate is loaded onto the substrate support of an etch chamber and a hafnium oxide layer was etched using a gas mixture of about 40 sccm chlorine gas and about 40 sccm carbon monoxide, and argon, having a chamber pressure of about 4 mTorr and a substrate temperature of about 250° C. No bias power was applied to the substrate support and a high RF source power of about 1000 Watts was applied to an antenna source to form a plasma.

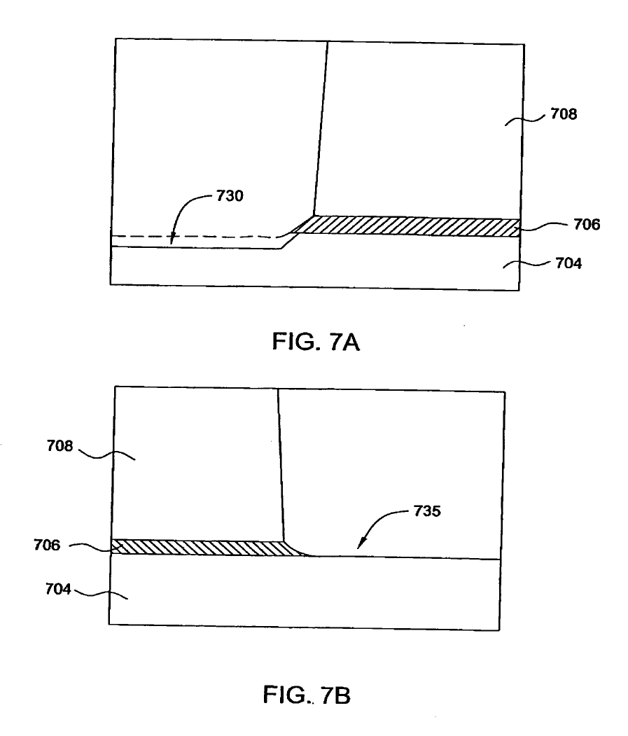

The result of the etching process is shown in FIG. 7A, illustrating a silicon dioxide substrate 704, an etched high-κ dielectric material layer 706, and a polysilicon layer 708. The etched high-κ dielectric material layer 706 includes a void space 730 (silicon recess) showing the attack of the silicon dioxide substrate 704 by the etch process which is undesirable for most semiconductor applications.

As a comparison, a low source power of about 400 Watts was used in addition to the Cl₂/CO chemistry under the same process parameters as described for FIG. 7A and the results are shown in FIG. 7B. As shown in FIG. 7B, the etched high-κ dielectric material layer 706 contained no void space (no silicon recess) near a region 735.

### EXAMPLE 3

A substrate is loaded onto the substrate support of an etch chamber and a hafnium oxide layer was etched using a two-step etch process. The etch process include a first gas mixture of about 100 sccm chlorine gas and about 5 sccm methane, and argon, having a chamber pressure of about 10 mTorr and a substrate temperature of about 250° C. No bias power was applied using the first gas mixture and a plasma was formed to etch a portion of the hafnium oxide layer. The hafnium-oxide layer was etched by the Cl₂/CH₄ chemistry at a rate of about 100 Å/min having an etch selectivity to SiO₂ of greater than 10:1. The etch selectivity to polysilicon is greater than 3:1.

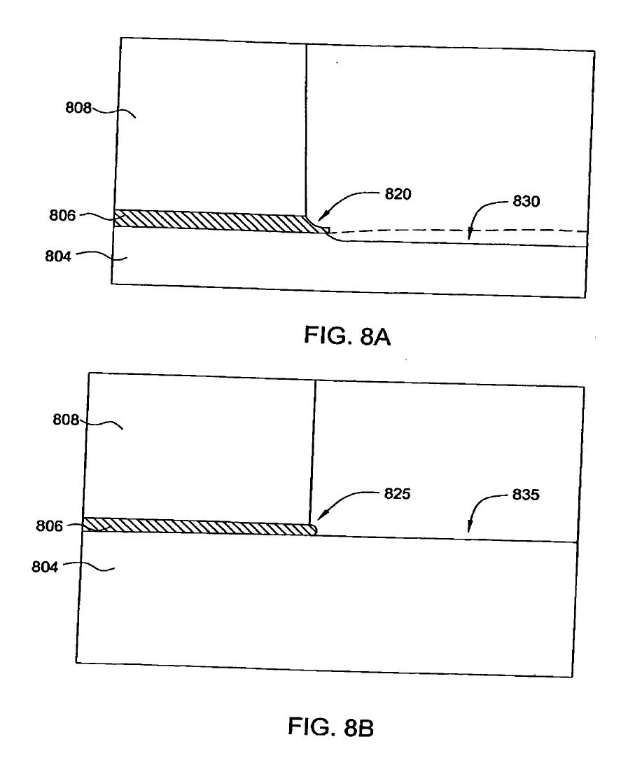

Next, a second gas mixture having about 40 sccm chlorine gas and about 40 sccm carbon monoxide, and argon, is used in the presence of a RF source power of about 400 Watts to form a plasma. The hafnium-oxide was etched by the Cl₂/CO chemistry at a rate of about 50 Å/min having an etch selectivity to SiO₂ of greater than 30:1. The selectivity to polysilicon is greater than 3:1. The result of the etching process is shown in FIG. 8B, illustrating a silicon dioxide substrate 804, an etched high-κ dielectric material layer 806, and a polysilicon layer 808.

As a comparison, the results of a conventional process are shown in FIG. 8A. The etched high-κ dielectric material layer 806 using conventional method contained a high-κ foot 820 and a void space 830 showing the formation of high-κ residues and silicon recess problems using prior art etch method. In contrast, using the method of the invention, there is no high-κ dielectric material residue (no high-κ foot) near a region 825 and no silicon recess problem near a region 835, as clearly shown in FIG. 8B.

The invention may be practiced in other etching equipment wherein the processing parameters may be adjusted to achieve acceptable etch characteristics by those skilled in the arts utilizing the teachings disclosed herein without departing from the spirit of the invention. While the foregoing is directed to embodiments of the present invention, other and further embodiments of the invention may be devised without departing from the basic scope thereof, and the scope thereof is determined by the claims that follow.

1. A method of plasma etching a substrate having a layer containing a high-κ material, comprising:
exposing the layer to a plasma formed from a first process gas mixture comprising a first halogen containing gas without introducing an oxygen containing gas inside an etch chamber;
etching at least a portion of the layer in a first etch step; and
etching the layer in a second etch step using a plasma formed from a second process gas mixture comprising a second halogen containing gas and carbon monoxide.

2. The method of claim 1, wherein the high-κ material comprises a material selected from the group consisting of hafnium dioxide, zirconium dioxide, hafnium silicon oxide, zirconium silicon oxide, tantalum dioxide, aluminum oxide, aluminum doped hafnium dioxide, and combinations thereof.

3. The method of claim 2, wherein the layer further comprises a material for gate electrode selected from the group consisting of tantalum, tantalum nitride, tantalum silicon nitride, titanium nitride, and combinations thereof.

4. The method of claim 1, wherein the first halogen containing gas comprises a chlorine containing gas.

5. The method of claim 4, wherein the chlorine containing gas is selected from the group consisting of chlorine gas (Cl₂), boron chloride (BCl₃), hydrogen chloride (HCl), and combinations thereof.

6. The method of claim 1, wherein the first process gas mixture further comprises a reducing agent.

7. The method of claim 6, wherein the reducing agent is a gas selected from the group consisting of methane(CH₄), ethane(C₂H₆), ethylene(C₂H₄), and combinations thereof.

8. The method of claim 1, wherein the first process gas mixture further comprises a gas selected from the group consisting of helium (He), argon (Ar), nitrogen gas (N₂), and combinations thereof.

9. The method of claim 1, wherein the second halogen containing gas comprises a chlorine containing gas.

10. The method of claim 9, wherein the chlorine containing gas is selected from the group consisting of chlorine gas (Cl₂), boron chloride (BCl₃), hydrogen chloride (HCl), and combinations thereof.

11. The method of claim 1, wherein the second process gas mixture further comprises a gas selected from the group consisting of helium (He), argon (Ar), nitrogen gas (N₂), and combinations thereof.

12. The method of claim 1, wherein etching at least a portion of the layer without oxidizing a portion of the substrate is performed at a low bias power of less than about 100 Watts.

13. The method of claim 12, wherein the bias power is set at zero.

14. The method of claim 1, wherein the first etch step is performed at a high substrate temperature of between about 150 degrees Celsius and about 350 degrees Celsius.

15. The method of claim 1, wherein the second etch step is performed at a source power of between about 200 W to about 800 W.

16. A method of plasma etching a substrate having a layer containing a high-κ material, comprising:
etching at least a portion of the layer with a plasma formed from a first process gas mixture comprising a first halogen containing gas at a substrate bias power of 100 W or less inside an etch chamber; and
etching the layer with a plasma formed from a second process gas mixture comprising a second halogen containing gas and carbon monoxide with a selectivity for the layer and at a source power of between about 200 W to about 800 W.

17. The method of claim 16, wherein the layer comprises a high-κ dielectric material selected from the group consisting of hafnium dioxide, zirconium dioxide, hafnium silicon oxide, zirconium silicon oxide, tantalum dioxide, aluminum oxide, aluminum doped hafnium dioxide, and combinations thereof.

18. The method of claim 17, wherein the layer further comprises a material for gate electrode selected from the group consisting of tantalum, tantalum nitride, tantalum silicon nitride, titanium nitride, and combinations thereof.

19. The method of claim 16, wherein the first halogen containing gas comprises a chlorine containing gas selected from the group consisting of chlorine gas (Cl₂), boron chloride (BCl₃), hydrogen chloride (HCl), and combinations thereof.

20. The method of claim 16, wherein the first process gas mixture further comprises a reducing agent selected from the group consisting of methane(CH₄), ethane(C₂H₆), ethylene(C₂H₄), and combinations thereof.

21. The method of claim 16, wherein the second halogen containing gas comprises a chlorine containing gas selected from the group consisting of chlorine gas (Cl₂), boron chloride (BCl₃), hydrogen chloride (HCl), and combinations thereof.

22. The method of claim 16, wherein etching at least a portion of the layer with the plasma formed from the first process gas mixture is performed at zero substrate bias power.

23. The method of claim 16, wherein etching at least a portion of the layer with the plasma formed from the first process gas mixture is performed at a high substrate temperature of between about 150° C. and about 350° C.

24. The method of claim 16, wherein the selectivity of the second process gas mixture for the layer to silicon oxide is greater than about 30:1.
